(19) United States
(12) Patent Application Publication
(10) Pub. No.: US 2012/0092814 A1
(43) Pub. Date: Apr. 19, 2012

(54) ELECTRONIC DEVICE AND KEY SUPPORTING STRUCTURE THEREOF

(75) Inventors: Chih-Ming Chang, Taipei County (TW); Szu-Wei Wang, Taipei County (TW); Chin-Hsu Lai, Taipei County (TW)

(73) Assignee: ALTEK CORPORATION, Hsinchu (TW)

(21) Appl. No.: 12/987,723

(22) Filed: Jan. 10, 2011

(30) Foreign Application Priority Data
Oct. 15, 2010 (TW) 099135350

(51) Int. Cl. H05K 7/00; H01H 13/76

(52) U.S. Cl. 361/679.01; 200/5 A

(57) ABSTRACT

An electronic device and a key supporting structure thereof are disclosed. The key supporting structure includes a main body, at least one operating key, and a supporting member. The main body includes an opening, within which the at least one operating key and a display device are located. The supporting member is located behind and corresponding to the at least one operating key for supporting the same. By providing the supporting member behind the operating key, the display device can be arranged to closely adjoin the operating key without the need of providing any frame structure between them while the electronic device can still have a structural strength satisfying product tests according to the relevant industry codes. Meanwhile, the display device can have the largest possible size on the electronic device.

### FIELD OF THE INVENTION

The present invention relates to an electronic device and a key supporting structure thereof; and more particularly to an electronic device with large-size display screen and a key supporting structure thereof.

### BACKGROUND OF THE INVENTION

A large-size display device capable of clearly displaying all functions has become one of many major components of a portable electronic device. To provide a complete operating interface on the portable electronic device, some physical operating keys are also required in addition to the display device. Since the portable electronic device provides only a very limited internal space, it is important to work out a structural design and an effective mechanism layout for simultaneously mounting the large-size display device and the physical operating keys on the small portable electronic device without causing surface deflection when the operating keys are downward pushed.

For the portable electronic device with large-size display device to pass key push tests conducted based on relevant industry codes, reinforcing ribs are usually provided for the display device and around the operating keys. FIG. 1 is a schematic front view of a conventional electronic device with operating keys. For a main body 1 of the electronic device to have sufficient rigidity to support the operating keys 2 when the same are downward pushed, a space 30 is provided between the operating keys 2 and the display device 4 and between the operating keys 2 and an adjacent edge of the main body 1, so that reinforcing ribs can be provided at these spaces 30. To provide the reinforcing ribs, there are some required conditions in the manufacturing process of the main body 1, such as the thickness, spacing and draft angle for the reinforcing ribs. To satisfy these manufacturing conditions, the above-mentioned spaces 30 are usually ranged between 0.2 mm and 0.5 mm, and preferably larger than 0.5 mm. Due to the required structural strength, the spaces 30 and the reinforcing ribs correspondingly provided thereat largely restrict the space available on the electronic device for the display device 4, and accordingly, the size of the display device 4.

### SUMMARY OF THE INVENTION

A primary object of the present invention is to provide an electronic device and a key supporting structure thereof, so that the electronic device has a main body with sufficient structural strength to support a large-size display device thereon.

To achieve the above and other objects, the key supporting structure according to the present invention includes a main body, at least one operating key, and a supporting member. The main body includes a first surface and an opposite second surface, and an opening provided on the first and second surfaces to extend through the two surfaces. The at least one operating key is provided on the first surface and located within the opening to closely adjoin an adjacent edge of the opening, such that a bottom of the operating key is located between the first and the second surface. The supporting member is located behind and corresponding to the at least one operating key, and has one side closely adjoining or in contact with the bottom of the operating key.

The supporting member is provided with a predetermined rigidity for supporting the operating key.

The supporting member includes a plurality of first connection sections, and the main body is provided on the second surface or two side walls adjacent to the second surface with a plurality of second connection sections corresponding to the first connection sections. The supporting member is connected to the main body via engagement of the first connection sections with the second connection sections.

The first and the second connection sections may be engaged with one another in different manners, including but not limited to hooking, screwing, welding, gluing, etc.

To increase the rigidity of the supporting member, the supporting member can be further provided with a plurality of reinforcing ribs, bent grooves, bent edges or stamped edges.

To achieve the above and other objects, the electronic device according to the present invention includes a key supporting structure, a display device, and a second main body. The key supporting structure includes a main body, at least one operating key, and a supporting member. The main body includes a first surface and an opposite second surface, and an opening provided on the first and second surfaces to extend through the two surfaces. The at least one operating key is provided on the first surface and located within the opening to closely adjoin an adjacent edge of the opening, such that a bottom of the operating key is located between the first and the second surface. The supporting member is located behind and corresponding to the at least one operating key, and has one side closely adjoining or in contact with the bottom of the operating key. The display device is located within the opening to closely adjoin the operating key, so as to occupy a whole area of the opening that is not occupied by the at least one operating key. The second main body is a mating member of the main body of the key supporting structure. When the second main body is assembled to the main body of the key supporting structure, a complete enclosure of the electronic device is provided.

The rigid supporting member includes a plurality of first connection sections, and the main body is provided on the second surface or two side walls adjacent to the second surface with a plurality of second connection sections corresponding to the first connection sections. The supporting member is connected to the main body via engagement of the first connection sections with the second connection sections.

The first and the second connection sections may be engaged with one another in different manners, including but not limited to hooking, screwing, welding, gluing, etc.

To increase the rigidity of the supporting member, the supporting member can be further provided with a plurality of reinforcing ribs, bent grooves, bent edges or stamped edges.

In the present invention, the electronic device is a smart cellular phone.

With the above arrangements, the electronic device and the key supporting structure thereof have one or more of the following advantages:

(1) Even if the conventional reinforcing ribs are omitted, the electronic device and the key supporting structure thereof can still have structural strength satisfying the required industry codes; and

(2) By eliminating the conventional reinforcing ribs, there is more space on the electronic device for mounting the display device, allowing the display device to have the largest possible size to create improved visual effect.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic front view of a conventional electronic device with operating keys;

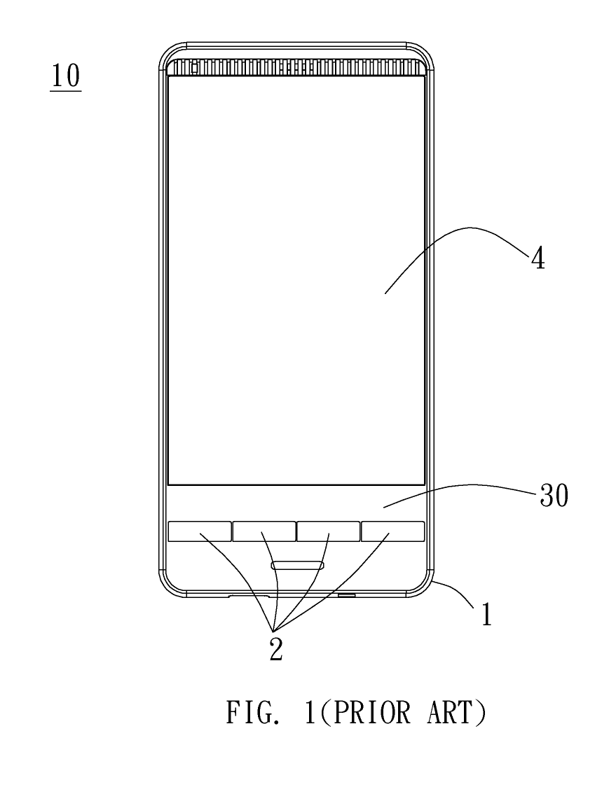

FIG. 2 is a schematic front view of a key supporting structure for electronic device according to the present invention;

FIG. 3 is a rear view of FIG. 2;

FIG. 4 is a fragmentary and enlarged rear view showing the key supporting structure for electronic device according to a first embodiment of the present invention;

FIG. 5 is a front view of an electronic device with a key supporting structure according to a second embodiment of the present invention;

FIG. 6 is a front view of an electronic device with a key supporting structure according to a third embodiment of the present invention; and

FIG. 7 is a front view of an electronic device with a key supporting structure according to a fourth embodiment of the present invention.

### DETAILED DESCRIPTION OF THE PREFERRED EMBODIMENTS

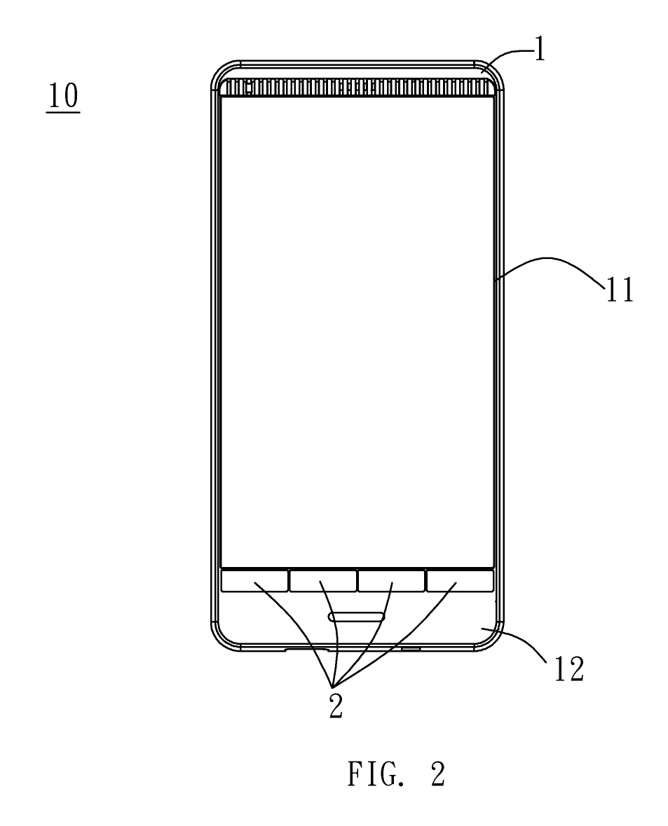

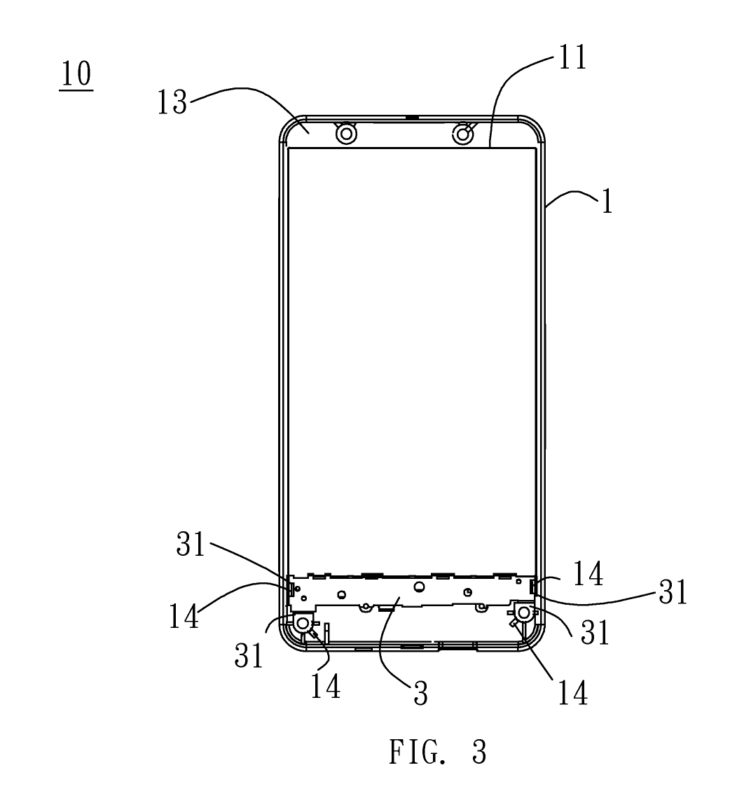

Please refer to FIGS. 2 and 3 that are schematic front and rear views, respectively, of a key supporting structure for electronic device according to the present invention. As shown, the key supporting structure, which is generally denoted by reference number 10, includes a main body 1, at least one operating key 2, and a supporting member 3. The main body 1 includes an opening 11, a first surface 12, and an opposite second surface 13. The opening 11 is correspondingly formed on the first and the second surface 12, 13 to extend through the same. In the illustrated embodiments, there are shown four operating keys 2. The operating keys 2 are located within the opening 11 to closely adjoin an adjacent edge of the opening 11 with bottoms of the operating keys 2 located between the first surface 12 and the second surface 13. The supporting member 3 is located at a position behind and corresponding to the operating keys 2, and includes a plurality of first connection sections 31. The main body 1 is provided on the second surface 13 and two opposite side walls adjacent to the second surface 13 at positions corresponding to the first connection sections 31 with a plurality of second connection sections 14. The supporting member 3 is connected to the main body 1 via engagement of the first connection sections 31 with the second connection section 14. The supporting member 3 must have sufficient rigidity to support the downward pushed operating keys 2. For this purpose, the supporting member 3 can be made of a metal material or a plastic material having good structural strength after being molded, or be formed with some structure enabling increased stiffness, such as reinforcing ribs, bent grooves, bent edges, stamped edges, etc., so as to obtain the required rigidity. The first connection sections 31 are preferably provided on the supporting member 3 at positions to where the largest possible pressure would be applied when the operating keys are downward pushed. However, for the second connection sections 14 to also function as a reinforcing structure to the main body 1, the positions of the second connection sections 14 on the main body 1 can be determined first, and the first connection sections 31 are then extended from the supporting member 3 at positions corresponding to the second connection sections 14. In the embodiment illustrated in FIG. 3, the first connection sections 31 are located at two opposite ends of the supporting member 3. However, it is understood the first connection sections 31 may be provided on the supporting member 3 at other different positions. The first connection sections 31 and the second connection sections 14 may be engaged with one another in different manners, including but not limited to screwing, hooking, welding, gluing, or any combination thereof. In the embodiment illustrated in FIG. 3, the first connection sections 31 and the second connection sections 14 are engaged with one another in two ways, namely, screwing and hooking.

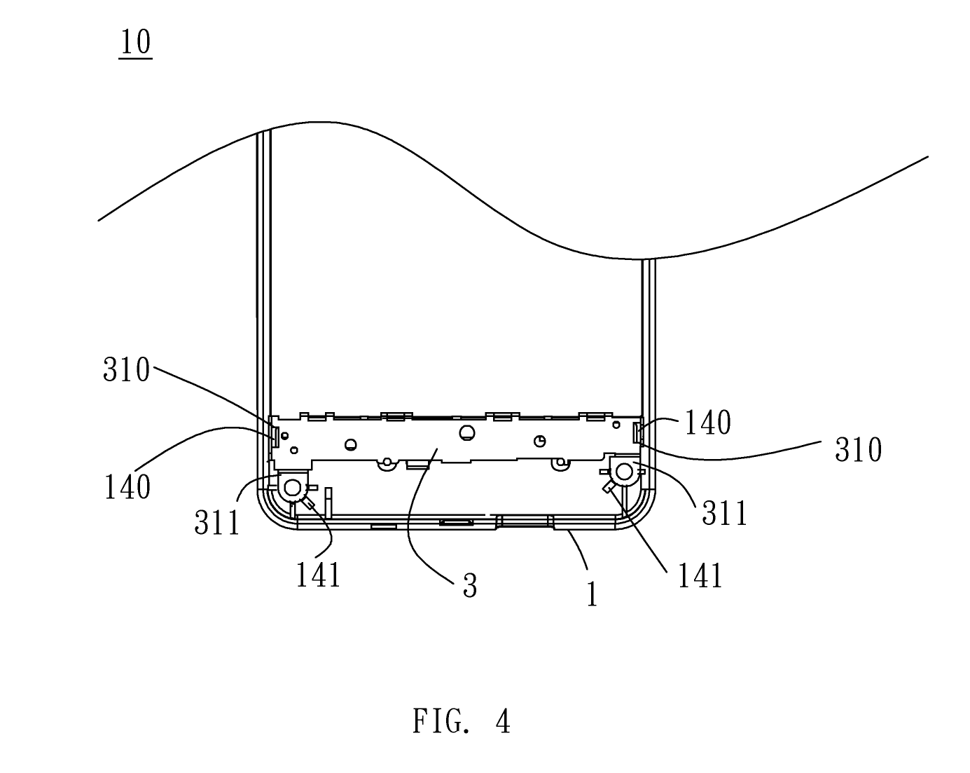

Please refer to FIG. 4 that is a fragmentary and enlarged rear view showing the key supporting structure for electronic device according to a first embodiment of the present invention. In this first embodiment, a first group of second connection sections 140 are hooks inward extended from the side walls of the main body 1 and located within the second surface 13, and a first group of first connection sections 310 are openings on the supporting member 3 for the second connection sections 140 to correspondingly hook and accordingly be retained thereto. Meanwhile, a second group of second connection sections 141 are internally threaded mounts extended from the second surface 13, and a second group of first connection sections 311 are openings on the supporting member 3 corresponding to the internally threaded mounts for screws to extend therethrough into the mounts.

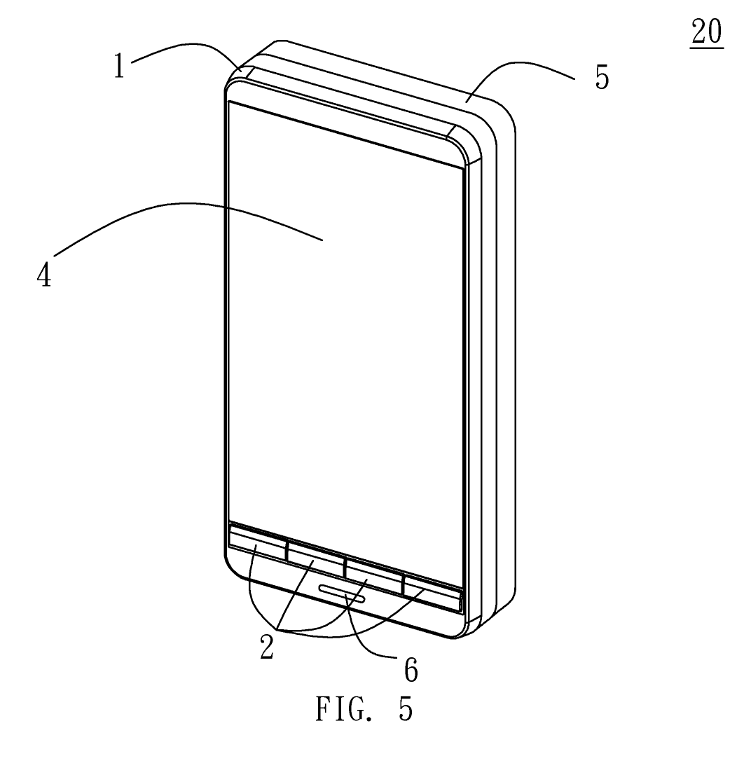

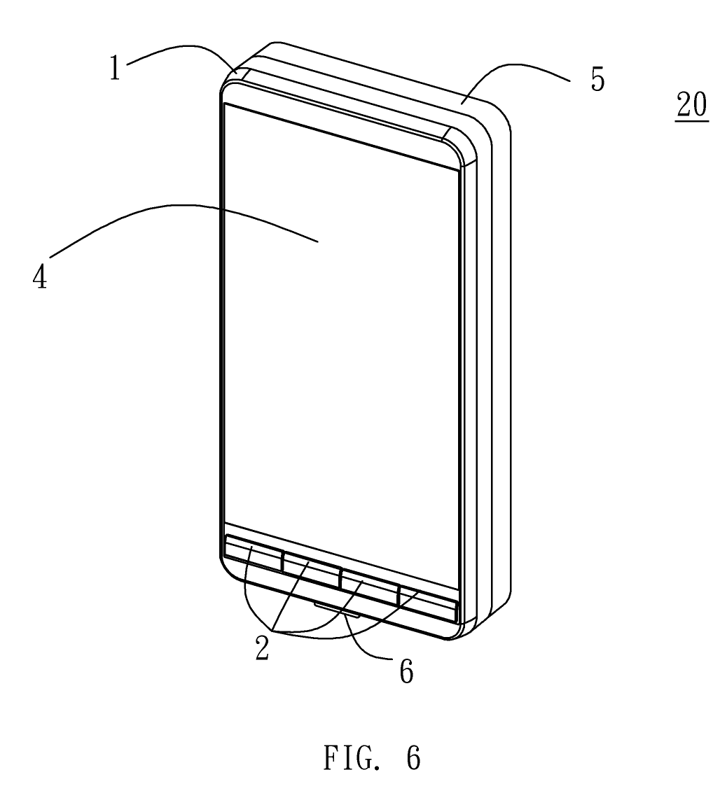

Please refer to FIG. 5 that is a front view of an electronic device with a key supporting structure according to a second embodiment of the present invention. As shown, the electronic device, which is generally denoted by reference number 20, is a multifunctional smart cellular phone, and includes a key supporting structure 10, a display device 4, and a second main body 5. The key supporting structure 10 is similar to that shown in FIGS. 2 and 3. The second main body 5 is associated with the main body 1 of the key supporting structure 10 to provide a complete enclosure of the electronic device 20. The display device 4 and the operating keys 2 are located within the opening 11. The operating keys 2 closely adjoins an adjacent edge of the opening 11, and the display device 4 closely adjoins the operating keys 2 with only a small clearance left between them, such that a display screen of the display device 4 occupies a whole area of the opening 11 that is not occupied by the operating keys 2. Some space between the operating keys 2 and the main body 1 may be reserved for some other electronic elements 6 that are to be visible from outside of the electronic device 20, such as a microphone or speakers. Alternatively, according to a third embodiment as shown in FIG. 6, the operating keys 2 may be located to closely adjoin a lower edge of the main body 1, so that the screen of the display device 4 is further expanded in size.

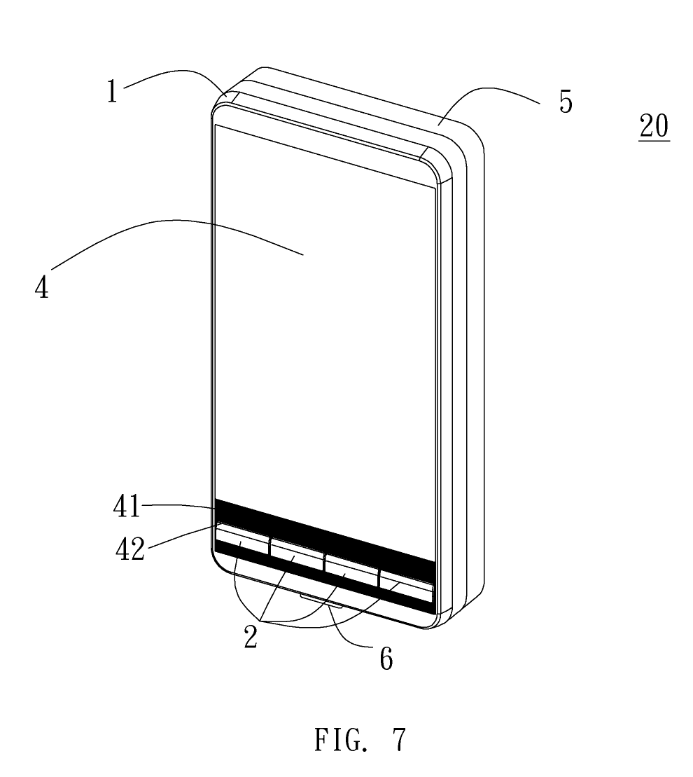

Please refer to FIG. 7 that is a front view of an electronic device 20 with a key supporting structure according to a fourth embodiment of the present invention. The electronic device 20 illustrated in FIG. 7 is generally structurally similar to that shown in FIG. 6 except that the screen of the display device 4 is provided with a key mounting opening 41 corresponding the arrayed operating keys 2. Any area on the screen near the key mounting opening 41 that is not for displaying is blackened and accordingly covered to form a black zone 42.

According to the present invention, since a supporting member 3 is provided behind the operating keys 2, the reinforcing ribs as provided on the conventional electronic device around the operating keys can be directly omitted while the electronic device can still satisfy the structural strength required by the relevant industry codes. Meanwhile, with the conventional reinforcing ribs omitted from the electronic device, the display device 4 can have increased screen size to create improved visual effect.

The present invention has been described with some preferred embodiments thereof and it is understood that many changes and modifications in the described embodiments can be carried out without departing from the scope and the spirit of the invention that is intended to be limited only by the appended claims.

What is claimed is:

1. A key supporting structure, comprising:
a main body having an opening, a first surface, and an opposite second surface; and the opening being correspondingly formed on the first and the second surface to extend through the two surfaces;
at least one operating key being located within the opening to closely adjoin an adjacent edge of the opening, and a bottom of the operating key being located between the first and the second surface; and
a supporting member being located at a position behind and corresponding to the operating key, and having one side closely adjoined or in contact with the bottom of the operating key.

2. The key supporting structure as claimed in claim 1, wherein the supporting member is provided with a predetermined rigidity for supporting the at least one operating key.

3. The key supporting structure as claimed in claim 2, wherein the supporting member includes a plurality of first connection section, and the main body is provided on the second surface or two opposite side walls adjacent to the second surface at positions corresponding to the first connection sections with a plurality of second connection sections; and wherein the supporting member is connected to the main body via engagement of the first connection sections with the second connection sections.

4. The key supporting structure as claimed in claim 3, wherein the first and the second connection sections are engaged by hooking, screwing, welding, or gluing.

5. The key supporting structure as claimed in claim 1, wherein the supporting member further includes rigidity-enhancing structures comprising reinforcing ribs, bent grooves, bent edges, or stamped edges.

6. An electronic device, comprising:
a key supporting structure including:
a main body having an opening, a first surface, and an opposite second surface; and the opening being correspondingly formed on the first and the second surface to extend through the two surfaces;
at least one operating key being located within the opening to closely adjoin an adjacent edge of the opening, and a bottom of the operating key being located between the first surface and the second surface;
a supporting member being located at a position behind and corresponding to the at least one operating key, and the supporting member having one side closely adjoining or in contact with the bottom of the operating key; and
a display device being located within the opening to closely adjoin the at least one operating key; and the display device occupying a whole area of the opening that is not occupied by the at least one operating key.

7. The electronic device as claimed in claim 6, wherein the supporting member is provided with a predetermined rigidity and includes a plurality of first connection section, and the main body is provided on the second surface or two opposite side walls adjacent to the second surface at positions corresponding to the first connection sections with a plurality of second connection sections; and wherein the supporting member is connected to the main body via engagement of the first connection sections with the second connection sections.

8. The electronic device as claimed in claim 7, wherein the first and the second connection sections are engaged with one another in hooking manner, screwing manner, welding manner, or gluing manner.

9. The electronic device as claimed in claim 8, wherein the supporting member further includes rigidity-enhancing structures comprising reinforcing ribs, bent grooves, bent edges, or stamped edges.

10. The electronic device as claimed in claim 9, wherein the electronic device is a smart cellular phone.
